(19) United States
(12) Patent Application Publication
(10) Pub. No.: US 2015/0206590 A1
(43) Pub. Date: Jul. 23, 2015

(54) MEMORY SYSTEM

(71) Applicant: Kabushiki Kaisha Toshiba, Minato-ku (JP)

(72) Inventors: Haruka SAKUMA, Yokohama (JP); Yoshiaki Fukuzumi, Yokkaichi (JP); Hideaki Aochi, Yokkaichi (JP); Hiroshi Sukegawa, Nerima (JP); Tokumasa Hara, Kawasaki (JP); Hiroshi Yao, Yokohama (JP); Shirou Fujita, Kamakura (JP); Ikuo Magaki, Kawasaki (JP); Kiwamu Sakuma, Yokohama (JP); Masumi Saitoh, Yokkaichi (JP)

(73) Assignee: Kabushiki Kaisha Toshiba, Minato-ku (JP)

(21) Appl. No.: 14/463,835

(22) Filed: Aug. 20, 2014

(30) Foreign Application Priority Data
Jan. 20, 2014 (JP) 2014-007790

(51) Int. Cl. G11C 16/14; G11C 16/26

(52) U.S. Cl. CPC G11C 16/14; G11C 16/26

(57) ABSTRACT

According to one embodiment, a memory system includes a nonvolatile semiconductor memory device and a controller. The system includes the nonvolatile semiconductor memory device including a plurality of memory cells; and the controller configured to control one of read operation, write operation, and a use frequency of the read operation or the write operation on the nonvolatile semiconductor memory device, and configured to change controlling for a memory cell belonging to a first group of the memory cells and to change controlling for a memory cell belonging to a second group located on an upper side or a lower side of the memory cell belonging to the first group.

### CROSS-REFERENCE TO RELATED APPLICATIONS

This application is based upon and claims the benefit of priority from Japanese Patent Application No. 2014-007790, filed on Jan. 20, 2014; the entire contents of which are incorporated herein by reference.

### FIELD

Embodiments described herein relate generally to a memory system.

### BACKGROUND

The integration and capacity of a nonvolatile semiconductor memory device can be increased by employing a structure in which memory cells are three-dimensionally stacked. However, with the increase of integration and capacity, a high level of processing technique is required and as a result the processing of memory cells may lack uniformity. For example, the processing may vary between an upper layer and a lower layer of a stacked body in which memory cells are three-dimensionally stacked. When there is a variation in the shape of memory cells, the characteristics of memory cells will vary, and the reliability of the nonvolatile semiconductor memory device may be reduced.

### BRIEF DESCRIPTION OF THE DRAWINGS

FIG. 1 is a schematic perspective view showing an overview of a memory cell array portion of a nonvolatile semiconductor memory device according to the first embodiment;

FIG. 2A is a schematic cross-sectional view of a memory cell portion according to the first embodiment, and FIG. 2B is schematic plan views of the memory cell portion according to the first embodiment;

FIG. 3 is a block diagram of a memory system according to the first embodiment;

FIG. 4A and FIG. 4B are diagrams showing examples of the shift reading;

FIG. 5A is a schematic cross-sectional view of a memory cell portion according to a second embodiment, and FIG. 5B is schematic plan views of the memory cell portion according to the second embodiment;

FIG. 6 is a schematic perspective view showing an overview of a memory cell array portion of a nonvolatile semiconductor memory device according to a third embodiment;

FIG. 7 is a schematic cross-sectional view of a memory cell portion according to the third embodiment;

FIG. 8A and FIG. 8B are schematic side views of memory cell portions according to a fourth embodiment;

FIG. 9 is a block diagram of a memory system according to a fifth embodiment;

FIG. 10 is a block diagram of a memory system according to a sixth embodiment; and

FIG. 11 is a block diagram of a memory system according to a seventh embodiment.

### DETAILED DESCRIPTION

According to one embodiment, a memory system includes a nonvolatile semiconductor memory device and a controller. The system includes the nonvolatile semiconductor memory device including a plurality of memory cells; and the controller configured to control one of read operation, write operation, and a use frequency of the read operation or the write operation on the nonvolatile semiconductor memory device, and configured to change controlling for a memory cell belonging to a first group of the memory cells and to change controlling for a memory cell belonging to a second group located on an upper side or a lower side of the memory cell belonging to the first group.

Various embodiments will be described hereinafter with reference to the accompanying drawings. In the following description, identical components are marked with the same reference numerals, and a description of components once described is omitted as appropriate. The drawings are schematic ones for describing the invention and promoting the understanding thereof; and the configuration, dimensions, ratios, etc. may be illustrated differently from those of the actual device. Design changes may be made to them as appropriate with consideration of the following description and known art.

### First Embodiment

Before describing a memory system according to a first embodiment, an overview of a nonvolatile semiconductor memory device incorporated into the memory system is described.

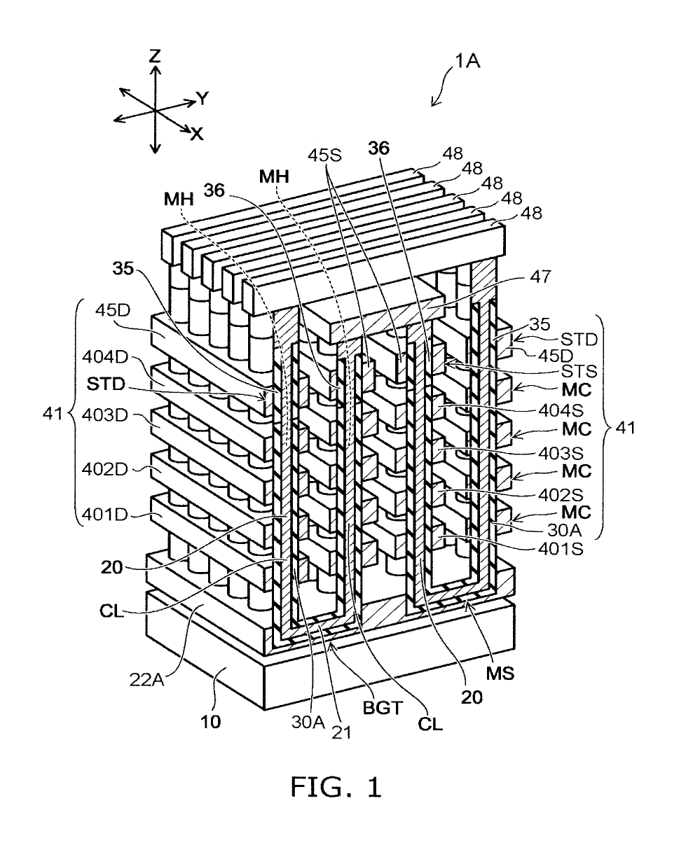

FIG. 1 is a schematic perspective view showing an overview of a memory cell array portion of a nonvolatile semiconductor memory device according to the first embodiment.

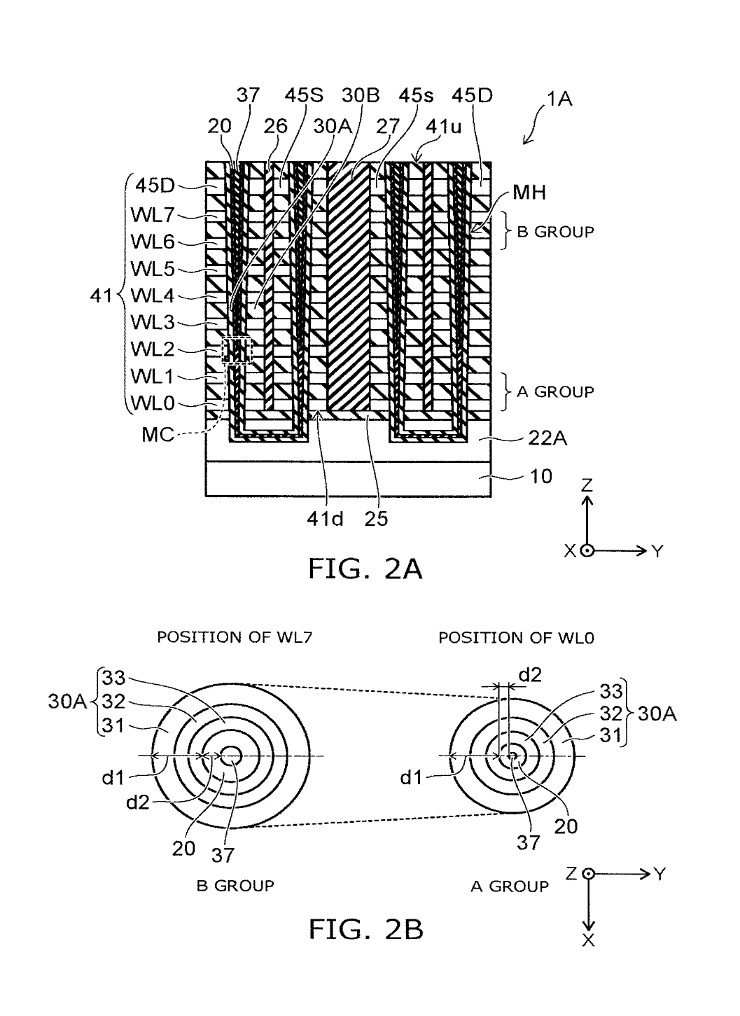

FIG. 2A is a schematic cross-sectional view of a memory cell portion according to the first embodiment, and FIG. 2B is schematic plan views of the memory cell portion according to the first embodiment.

In FIG. 1, the illustration of insulating portions other than an insulating film formed on the inner wall of a memory hole MH is omitted for easier viewing of the drawing.

In FIG. 1, an XYZ orthogonal coordinate system is introduced for convenience of description. In the coordinate system, two directions parallel to the major surface of a substrate 10 and orthogonal each other are defined as the X-direction and the Y-direction, and the direction orthogonal to both the X-direction and the Y-direction is defined as the Z-direction.

A nonvolatile semiconductor memory device 1A is a NAND nonvolatile memory that can perform the erasing and writing of data electrically in a free manner and can retain memory content even when the power is turned off. The nonvolatile semiconductor memory device 1A illustrated in FIG. 1 is commonly called a BiCS (bit cost scalable) flash memory.

In the nonvolatile semiconductor memory device 1A, a back gate 22A is provided on the substrate 10 via a not-shown insulating layer. A unit including the substrate 10 and the insulating layer is referred to as an underlayer. The substrate 10 is a silicon substrate, for example. In the substrate 10, an active element such as a transistor and a passive element such as a resistance and a capacitance may be provided. The back gate 22A is a silicon (Si)-containing layer doped with an impurity element, for example.

In FIG. 1, electrode layers 401D, 402D, 403D, and 404D on the drain side and electrode layers 401S, 402S, 403S, and 404S on the source side are stacked on the back gate 22A, as an example. An insulating layer (not shown) is provided between the over and underlying electrode layers.

The electrode layer 401D and the electrode layer 401S are provided on the same stage, and show the lowermost electrode layer. The electrode layer 402D and the electrode layer 402S are provided on the same stage, and show the second lowest electrode layer. The electrode layer 403D and the electrode layer 403S are provided on the same stage, and show the third lowest electrode layer. The electrode layer 404D and the electrode layer 404S are provided on the same stage, and show the fourth lowest electrode layer.

The electrode layer 401D and the electrode layer 401S are divided in the Y-direction. The electrode layer 402D and the electrode layer 402S are divided in the Y-direction. The electrode layer 403D and the electrode layer 403S are divided in the Y-direction. The electrode layer 404D and the electrode layer 404S are divided in the Y-direction.

A not-shown insulating layer is provided between the electrode layer 401D and the electrode layer 401S, between the electrode layer 402D and the electrode layer 402S, between the electrode layer 403D and the electrode layer 403S, and between the electrode layer 404D and the electrode layer 404S.

The electrode layers 401D, 402D, 403D, and 404D are provided between the back gate 22A and a drain-side select gate electrode 45D. The electrode layers 401S, 402S, 403S, and 404S are provided between the back gate 22A and a source-side select gate electrode 45S.

The number of electrode layers 401D, 402D, 403D, 404D, 401S, 402S, 403S, and 404S is arbitrary and not limited to four illustrated in FIG. 1. For example, eight electrode layers may be provided as shown in FIG. 2A. In the embodiment, the electrode layers 401D, 402D, 403D, 404D, 401S, 402S, 403S, and 404S may be referred to collectively and simply as an electrode layer WL. The electrode layer WL is a conductive silicon-containing layer doped with an impurity element such as boron (B), for example.

The drain-side select gate electrode 45D is provided on the electrode layer 404D via a not-shown insulating layer. The drain-side select gate electrode 45D is a silicon-containing layer with electrical conductivity doped with an impurity, for example. The source-side select gate electrode 45S is provided on the electrode layer 404S via a not-shown insulating layer. The source-side select gate electrode 45S is a silicon-containing layer with electrical conductivity doped with an impurity, for example.

The drain-side select gate electrode 45D and the source-side select gate electrode 45S are divided in the Y-direction. The drain-side select gate electrode 45D and the source-side select gate electrode 45S may be referred to simply as a select gate electrode 45 without being distinguished.

A source line 47 is provided on the source-side select gate electrode 45S via a not-shown insulating layer. The source line 47 is connected to one of a pair of channel body layers 20. The source line 47 is a metal layer or a silicon-containing layer with electrical conductivity doped with an impurity.

A plurality of bit lines 48 are provided on the drain-side select gate electrode 45D and the source line 47 via a not-shown insulating layer. The bit line 48 is connected to the other of the pair of channel body layers 20. The bit line 48 extends in the Y-direction.

A plurality of U-shaped memory holes MH are formed in the back gate 22A and a stacked body 41 on the back gate 22A. The memory hole MH is a through hole before forming the channel body layer 20 and a memory layer 30A. For example, in the electrode layers 401D to 404D and the drain-side select gate electrode 45D, a hole piercing them and extending in the Z-direction is formed. In the electrode layers 401S to 404S and the source-side select gate electrode 45S, a hole piercing them and extending in the Z-direction is formed. The pair of holes extending in the Z-direction are connected together via a recess (space) formed in the back gate 22A to form the U-shaped memory hole MH.

The channel body layer 20 is provided in a U-shaped configuration in the memory hole MH. The channel body layer 20 is a silicon-containing layer, for example. The memory layer 30A is provided between the channel body layer 20 and the inner wall of the memory hole MH.

A gate insulating film 35 is provided between the channel body layer 20 and the drain-side select gate electrode 45D. A gate insulating film 36 is provided between the channel body layer 20 and the source-side select gate electrode 45S.

The drain-side select gate electrode 45D, the channel body layer 20, and the gate insulating film 35 between them constitute a drain-side select transistor STD. The channel body layer 20 above the drain-side select transistor STD is connected to the bit line 48.

The source-side select gate electrode 45S, the channel body layer 20, and the gate insulating film 36 between them constitute a source-side select transistor STS. The channel body layer 20 above the source-side select transistor STS is connected to the source line 47.

The back gate 22A, and the channel body layer 20 and the memory layer 30A provided in the back gate 22A constitute a back gate transistor BGT.

A plurality of memory cells MC using the electrode layers 404D to 401D as control gates are provided between the drain-side select transistor STD and the back gate transistor BGT. Similarly, a plurality of memory cells MC using the electrode layers 401S to 404S as control gates are provided between the back gate transistor BGT and the source-side select transistor STS.

The plurality of memory cells MC, the drain-side select transistor STD, the back gate transistor BGT, and the source-side select transistor STS are connected in series via the channel body layer to constitute one U-shaped memory string MS.

One memory string MS includes a pair of columnar portions CL extending in the stacking direction of the stacked body 41 including a plurality of electrode layers and a connection portion 21 embedded in the back gate 22A and connecting the pair of columnar portions CL. The memory string MS is arranged in plural in the X-direction and the Y-direction; thus, a plurality of memory cells are provided three-dimensionally in the X-direction, the Y-direction, and the Z-direction.

FIG. 2A shows an example in which eight electrode layers WL are stacked on the substrate 10. In FIG. 2A, the electrode layers are marked with WL0 to WL7 from bottom to top. The reference numerals WL0 to WL7 are used for the electrode layers on both the drain side and the source side. FIG. 2B shows cross sections of a plurality of memory cells MC taken along the direction orthogonal to the stacking direction of the stacked body 41 (the Z-direction). FIG. 2B shows cross sections of the channel body layer 20 and the memory layer 30A in the positions of the electrode layers WL0 and WL7 in the X-Y plane, for example.

As shown in FIG. 2A, the stacked body 41 is provided on the substrate 10 via the back gate 22A and an insulating layer 25. In the stacked body 41, the plurality of electrode layers WL0 to WL7 and a plurality of insulating layers 30B are alternately stacked. The stacked body 41 further includes the select gate electrodes 45D and 45S. The insulating layer 30B contains silicon oxide, for example. The stacked body 41 is divided in the Y-direction by insulating layers 26 and 27.

The channel body layer 20 extends from the upper end 41u of the stacked body 41 to the lower end 41d of the stacked body 41. The memory layer 30A is provided between the channel body layer 20 and each of the plurality of electrode layers WL0 to WL7. As shown in FIG. 2B, the memory layer 30A is surrounded by each of the plurality of electrode layers WL0 to WL7. The memory layer 30A surrounds the channel body layer 20.

The memory cell MC includes the memory layer 30A, the channel body layer 20 in contact with the memory layer 30A, and the electrode layer WL in contact with the memory layer 30A. Memory cells MC are arranged in the X-direction, the Y-direction, and the Z-direction in the nonvolatile semiconductor memory device 1A.

The memory layer 30A includes an insulating film 31 that is a block insulating film, a charge storage film 32, and an insulating film 33 that is a tunnel insulating film. The insulating film 33, the charge storage film 32, and the insulating film 31 are provided in this order from the channel body layer 20 side to the outside between each of the electrode layers WL0 to WL7 and the channel body layer 20, for example. The channel body layer 20 surrounds an insulating layer 37 that is a core material.

The memory layer 30A has an ONO (oxide-nitride-oxide) structure in which a silicon nitride film is sandwiched by a pair of silicon oxide films, for example. The insulating film 31 is in contact with each of the electrode layers WL0 to WL7, the insulating film 33 is in contact with the channel body layer 20, and the charge storage film 32 is provided between the insulating film 31 and the insulating film 33. The insulating film 31 contains silicon oxide, for example. The charge storage film 32 contains silicon nitride, for example. The insulating film 33 contains silicon oxide, for example.

The channel body layer 20 functions as a channel in a transistor forming a memory cell. The electrode layers WL0 to WL7 function as control gate electrodes. The periphery of the channel body layer 20 is surrounded by the control gate electrode. The charge storage film 32 functions as a data memory layer that stores a charge injected from the channel body layer 20.

Thus, the memory cell MC is formed at the intersections of the channel body layer 20 and the electrode layers WL0 to WL7. Also a structure in which the portion of the insulating layer 37, which is a core material, is filled up with the channel body layer 20 in place of the insulating layer 37 is included in the first embodiment.

In the memory string MS shown in FIG. 1, the memory hole MH is processed by RIE (reactive ion etching). At this time, the inner wall of the memory hole MH extending in the direction perpendicular to the substrate 10 (the Z-direction) may form a tapered shape (see FIG. 2A). As a result, the hole diameter of the memory hole MH is larger in an upper layer of the stacked body 41, and is smaller in a lower layer. In the first embodiment, the memory layer 30A with a uniform film thickness and the channel body layer 20 with a uniform film thickness are provided in such a memory hole MH having a variation in hole diameter.

Memory cells MC belonging to lower layers of the plurality of memory cells MC are referred to as an A group, and memory cells MC belonging to upper layers are referred to as a B group, for example.

In the case where a plurality of memory cells MC are classified into the A group and the B group different from the A group, the characteristics of the plurality of memory cells MC included in the nonvolatile semiconductor memory device 1A may be different between the A group and the B group of the plurality of memory cells MC. Here, the characteristics are data write characteristics, data erase characteristics, data read characteristics, endurance, data retention characteristics, etc., for example. In addition to these characteristics, the characteristics include the characteristics disclosed in this specification.

The first embodiment provides a memory system that makes control matched with the characteristics of the memory cell MC belonging to the A group and the memory cell MC belonging to the B group.

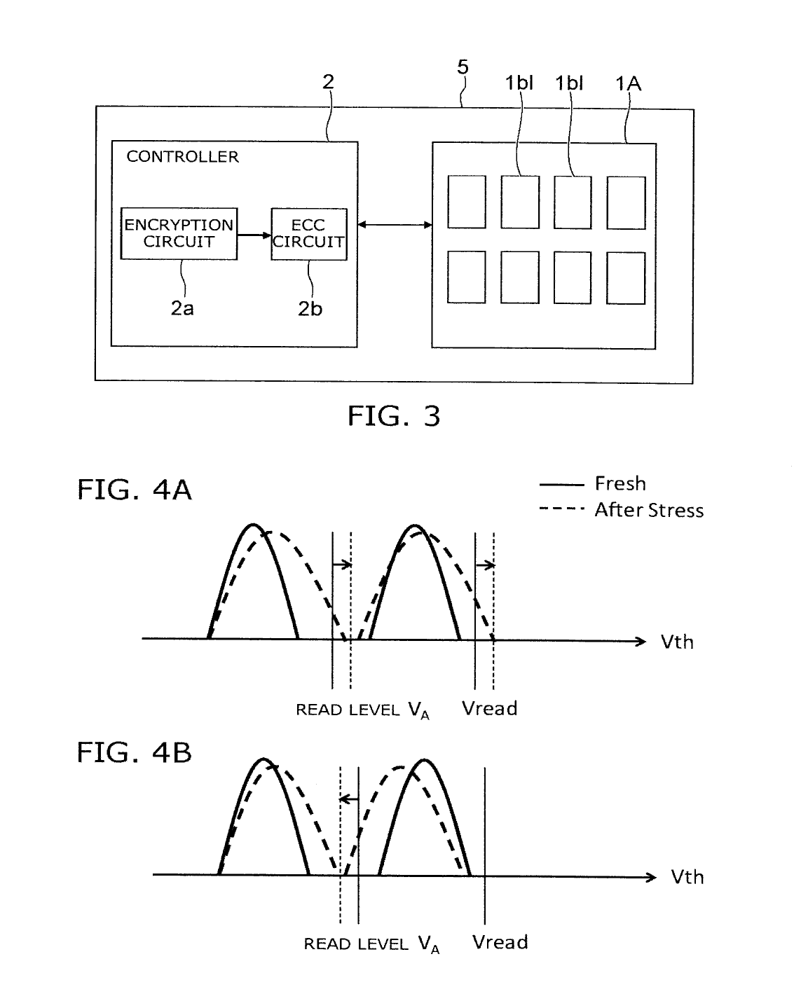

FIG. 3 is a block diagram of a memory system according to the first embodiment.

A memory system 5 includes the nonvolatile semiconductor memory device 1A and a controller 2 that controls the nonvolatile semiconductor memory device 1A. The nonvolatile semiconductor memory device incorporated into the memory system 5 may be also nonvolatile semiconductor memory devices 1B to 1E described later. Here, the nonvolatile semiconductor memory device 1A includes a plurality of memory cells MC. The controller 2 controls one of the read operation and the write operation on the nonvolatile semiconductor memory device 1A, the use frequency of the read operation or the write operation, etc. The controller 2 can change controlling for the memory cell MC belonging to a prescribed group of the plurality of memory cells MC and also for memory cell MC belonging to another group different from the prescribed group.

At least one memory cell MC belongs to the group. Here, a collection of a plurality of memory cells MC located in lower layers may be taken as the A group, and a collection of a plurality of memory cells MC located in upper layers may be taken as the B group. Alternatively, a collection of a plurality of memory cells MC located in upper layers may be taken as the A group, and a collection of a plurality of memory cells MC located in lower layers may be taken as the B group. That is, the A group is located on the upper side of the B group or on the lower side of the B group.

The nonvolatile semiconductor memory device 1A has a plurality of blocks 1bl, for example. The block 1bl is a collection in which the memory string MS shown in FIG. 1 is arranged up to a prescribed number in the X direction and the Y direction. Each of the plurality of blocks 1bl includes a prescribed number of memory cells MC.

The controller 2 makes the following control in the case where the characteristics mentioned above of the plurality of memory cells MC in one block 1bl of the nonvolatile semiconductor memory device 1A are different between the A group and the B group. The controller 2 can change the use frequency of at least one of the read operation, the write operation, and the erase operation on the memory cell MC between the A group and the B group. Here, the use frequency is the use degree load, such as the number of times of at least one of the read operation, the write operation, and the erase operation on the memory cell MC. An encryption circuit 2a, an ECC (error checking and correction) circuit 2b, etc. are incorporated in the controller 2.

The film thickness d1 of the memory layer 30A shown in FIG. 2B is equal between the A group and the B group. The film thickness d2 of the channel body layer 20 is equal between the A group and the B group. However, the cross-sectional area of the memory layer 30A is different between the A group and the B group. This is because the hole diameter of the memory hole MH is different between the A group and the B group. For example, the cross-sectional area of the memory layer 30A is larger in the B group than in the A group. Therefore, the curvature (1/radius) of the memory layer 30A surrounding the channel body layer 20 is higher in the A group than in the B group.

In such a case, the tunnel electric field applied to the insulating film 33 is applied more easily to the memory layer 30A belonging to the A group than to the memory layer 30A belonging to the B group. Therefore, the electrode layer WL belonging to the A group can operate the memory cell MC at a lower programming voltage (Vpgm) or a lower erase voltage (Vera) than the memory layer 30A of the B group. Thereby, the voltage applied to the memory layer 30A is reduced, and therefore the endurance characteristics of the memory cell MC are improved. The programming voltage may be referred to as a write voltage.

The controller 2 can control the nonvolatile semiconductor memory device 1A such that the number of times of writing of data to be stored in either of the memory cell MC belonging to the A group and the memory cell MC belonging to the B group and the number of times of writing of data to be stored in the other of the memory cell MC belonging to the A group and the memory cell MC belonging to the B group are different.

For example, data of a larger number of times of writing repeated are written preferentially on the memory cell MC belonging to the A group having better endurance than the B group. In addition to writing, data of large numbers of times of erasing and reading repeated are written preferentially on the memory cell MC belonging to the A group having better endurance than the B group. Thereby, the reliability of the memory system is improved.

The controller 2 can control the nonvolatile semiconductor memory device 1A such that the update frequency of data stored in either of the memory cell MC belonging to the A group and the memory cell MC belonging to the B group and the update frequency of data stored in the other of the memory cell MC belonging to the A group and the memory cell MC belonging to the B group are different.

For example, the controller 2 can write data of which the update frequency is estimated as high (for example, control data etc.) more preferentially on the memory cell MC belonging to the A group than on the B group. Since the controller 2 selects a memory cell MC with higher reliability and distribute data to this memory cell MC, the reliability of the nonvolatile semiconductor memory device 1A is improved.

The controller 2 can control the nonvolatile semiconductor memory device 1A such that the storage time of data stored in either of the memory cell MC belonging to the A group and the memory cell MC belonging to the B group and the storage time of data stored in the other of the memory cell belonging to the A group and the memory cell MC belonging to the B group are different.

For example, the controller 2 can write basic host data and important data more preferentially on the memory cell MC belonging to the A group than on the B group. By host data and important data being written more preferentially on the memory cell MC belonging to the A group than on the B group, a highly reliable memory system is constructed.

The controller 2 can control the nonvolatile semiconductor memory device 1A such that the difference between the maximum value and the minimum value of the threshold voltage of the electrode layer WL when data are written on either of the memory cell MC belonging to the A group and the memory cell MC belonging to the B group and the difference between the maximum value and the minimum value of the threshold voltage of the electrode layer WL when data are written on the other of the memory cell MC belonging to the A group and the memory cell MC belonging to the B group are different.

Furthermore, the controller 2 can control the nonvolatile semiconductor memory device 1A such that the difference between the maximum value and the minimum value of the threshold voltage of the electrode layer WL when data are erased from either of the memory cell MC belonging to the A group and the memory cell MC belonging to the B group and the difference between the maximum value and the minimum value of the threshold voltage of the electrode layer WL when data are erased from the other of the memory cell MC belonging to the A group and the memory cell MC belonging to the B group are different.

The controller 2 can set the budget of the threshold voltage (Vth) in writing or erasing (the allocation of Vth) to different values between the A group and the B group, for example. This is because the flexibility of setting the threshold voltage (window width) is different between the A group and the B group. The controller 2 uses each memory cell MC in a range with high reliability.

Even when the same threshold voltage is applied to the A group and the B group, the electric field is applied more easily to the insulating film 33 in the A group than to the B group because the hole diameter of the memory hole MH is smaller in the A group, for example. Thus, the window width of the threshold voltage is wider in the A group. In the A group, the budget of the threshold voltage is set in a range of −3 V to 8 V, for example.

On the other hand, the electric field is applied less easily to the insulating film 33 in the B group than to the A group because the hole diameter of the memory hole MH is larger in the B group. Thus, the window width of the threshold voltage is narrower in the B group. Here, erase operation at a strong erase voltage may cause cycle stress; hence, in the B group the budget of the threshold voltage may be set in a range of −2 V to 9 V. Thereby, the stress applied to the insulating film 33 is relaxed. Thus, the threshold voltage in each memory cell MC can be set in a range with high reliability.

The controller 2 can, when data cannot be read normally from a memory cell MC, alter the threshold voltage of this memory cell MC to perform shift read operation so that data stored in this memory cell MC can be read properly.

For example, when the controller 2 has searched an optimum shift value in the A group or the B group, the controller 2 calculates the shift value using a simple formula for the other memory cells MC, and sets a different shift value for each memory cell MC. By optimizing the shift value in shift reading, false reading of data is reduced. The controller 2 can shift the electric potential (for example, the threshold voltage (Vth)) of the electrode layer WL when data are written on one of the plurality of memory cells MC, or shift the electric potential of the electrode layer WL when data are erased from one of the plurality of memory cells MC. Thereby, the shift value in shift reading is optimized, and errors of data reading are reduced.

FIG. 4A and FIG. 4B are diagrams showing examples of the shift reading. Here, FIG. 4A shows an example of the shift reading to the plus side, and FIG. 4B shows an example of the shift reading to the minus side.

As shown in FIG. 4A, for a memory cell MC after repeated operation and for a memory cell MC that has experienced the influence of program disturb (PD), which is degradation after writing, read disturb (RD), which is degradation after reading, or data retention (DR), the read level VA for reading the threshold voltage is set higher than the read level of the initial setting (the line of Fresh in the drawing).

For example, in the case where the memory cell MC has experienced the influence of PD or RD, the distribution of the threshold voltage of the memory cell MC may become higher as shown by the solid line to the broken line (After Stress). Thus, the read voltage (level) VA for reading each threshold voltage initially set and the read voltage Vread supplied to the not-selected cell are lower than each threshold voltage that has changed; consequently, data cannot be read properly.

In the first embodiment, the read level is variable in accordance with the use conditions of the nonvolatile semiconductor memory device. That is, when data are read from a memory cell MC that has experienced the influence of PD or RD, the read level VA is set higher than the read level of the initial setting as shown by the broken line in FIG. 4A. Hence, the read level VA is located between the threshold voltage distributions; thus, data can be read properly. Also the read voltage Vread is set higher than the read level of the initial setting. Hence, the read voltage Vread is set higher than the highest threshold voltage distribution; thus, data can be read properly.

As shown in FIG. 4B, in the case where the memory cell MC has experienced the influence of DR, the distribution of the threshold voltage of the memory cell MC may change so as to become lower as shown by the solid line to the broken line. Hence, the read level VA for reading each threshold voltage set in the initial setting is higher than each threshold voltage that has changed; consequently, data cannot be read properly.

In such a case, the read level VA is set lower than the read level of the initial setting as shown by the broken line in FIG. 4B. Hence, the read level VA is located between the threshold voltage distributions; thus, data can be read properly.

The controller 2 can multiplex data and store the data in one of the plurality of memory cells MC. For example, data may be multiplexed, not made into two values, and be stored in each memory cell MC of the A group and the B group. By the multiple-valued storage, a memory system good in a reliability mode is constructed. It is also possible to construct a memory system in which a logical block is configured such that a memory cell MC in an upper layer and a memory cell MC in a lower layer coexist and encoding is made. Thus, using a product code, the efficiency of remedying error data is increased.

### Second Embodiment

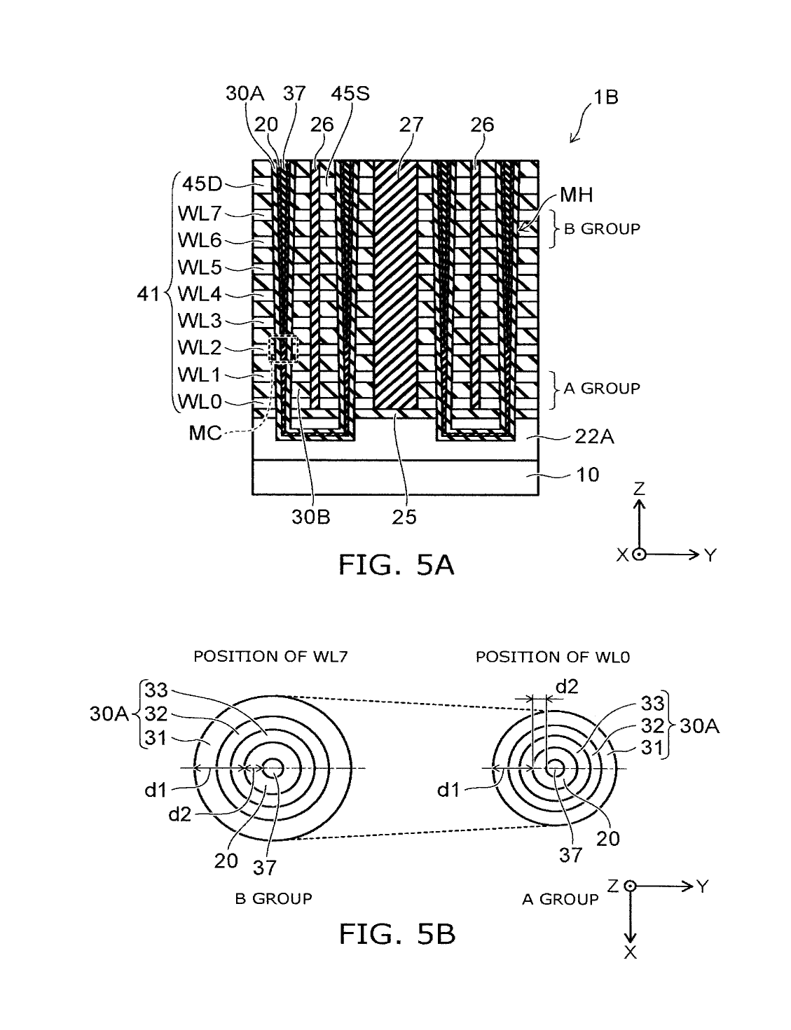

FIG. 5A is a schematic cross-sectional view of a memory cell portion according to a second embodiment, and FIG. 5B is schematic plan views of the memory cell portion according to the second embodiment.

The nonvolatile semiconductor memory device incorporated into the memory system 5 may be also a nonvolatile semiconductor memory device 1B illustrated below.

Also in the nonvolatile semiconductor memory device 1B according to the second embodiment, the memory hole MH extending in the direction perpendicular to the substrate 10 (the Z-direction) has a tapered shape. In other words, the hole diameter of the memory hole MH varies between an upper layer and a lower layer. For example, the hole diameter of the memory hole MH is larger in an upper layer of the stacked body 41, and is smaller in a lower layer of the stacked body 41.

In the nonvolatile semiconductor memory device 1B, the thickness of the channel body layer 20 is different between the A group and the B group in directions (the X-direction and the Y-direction) orthogonal to the stacking direction of the stacked body 41 (the Z-direction). The thickness of the memory layer 30A is different between the A group and the B group in directions orthogonal to the stacking direction. For example, the film thickness d1 of the memory layer 30A and the film thickness d2 of the channel body layer 20 are thinner in a lower layer (the A group) than in an upper layer (the B group) of the stacked body 41.

In the second embodiment, the controller 2 can control the nonvolatile semiconductor memory device 1B such that the write speed when data are written on either of the memory cell MC belonging to the A group and the memory cell MC belonging to the B group and the write speed when data are written on the other of the memory cell MC belonging to the A group and the memory cell MC belonging to the B group are different.

Furthermore, the controller 2 can control the nonvolatile semiconductor memory device 1B such that the erase speed when data are erased from either of the memory cell MC belonging to the A group and the memory cell MC belonging to the B group and the erase speed when data are erased from the other of the memory cell MC belonging to the A group and the memory cell MC belonging to the B group are different.

As the film thickness d2 of the channel body layer 20 becomes thicker, the resistance of the channel body layer 20 becomes lower and it becomes more likely that a GIDL (gate-induced drain leakage) current will flow through the channel body layer, for example. Alternatively, as the film thickness d2 of the channel body layer 20 becomes thicker, the carrier density in the channel body layer becomes higher. Thus, data for which a certain write/erase speed is required are written by the controller 2 preferentially on the memory cell MC of the B group in which the resistance of the channel body layer 20 is lower and the carrier density is higher.

Since the memory layer 30A is formed thinner in the A group than in the B group, the memory cell MC belonging to the A group is more susceptible to read disturb (RD) than the memory cell MC belonging to the B group. Thus, data of a large number of times of reading are written by the controller 2 more preferentially on the memory cell MC belonging to the B group, in which the memory layer 30A is thicker, than on the memory cell MC belonging to the A group. Thereby, the nonvolatile semiconductor memory device 1B becomes less susceptible to read disturb (RD), and the reliability of the memory system is improved.

The film thickness d1 of the memory layer 30A is thinner in the A group than in the B group. Thereby, the controller 2 can operate the memory cell MC belonging to the A group at a lower programming voltage/erase voltage than the memory cell MC belonging to the B group. By making such control, the degradation in the data retention characteristics of the memory system is reduced.

The insulating films 31 and 33 in the memory layer 30A may have carrier trapping properties. Electrons are likely to be trapped in a layer other than the charge storage film 32, and this will be a factor in the degradation of data retention characteristics. Thus, data of which the number of times of reading is small and for which long time retention is required are written by the controller 2 more preferentially on the memory cell MC belonging to the A group than on the memory cell MC belonging to the B group. Thereby, the reliability of the memory system is improved.

### Third Embodiment

The nonvolatile semiconductor memory device incorporated into the memory system 5 may be also a nonvolatile semiconductor memory device 1C illustrated below.

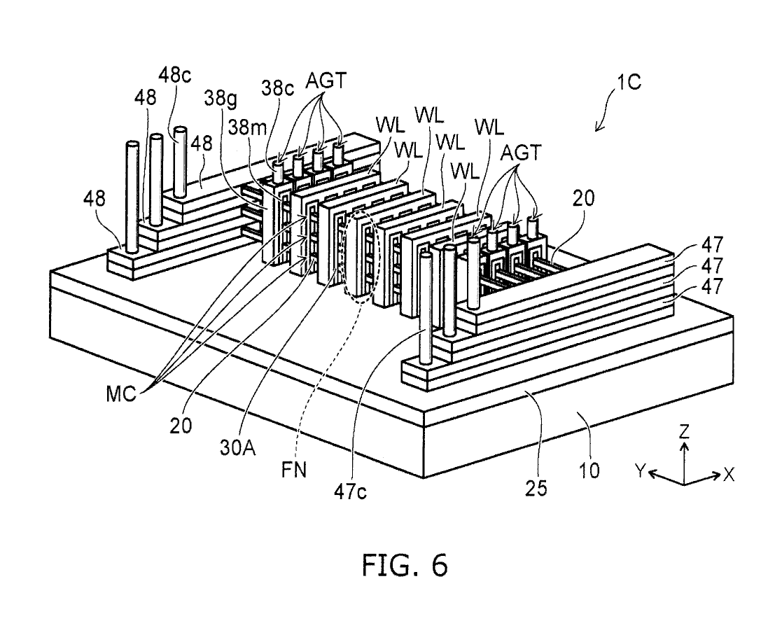

FIG. 6 is a schematic perspective view showing an overview of a memory cell array portion of a nonvolatile semiconductor memory device according to a third embodiment.

In the nonvolatile semiconductor memory device 1C according to the third embodiment, the electrode layer WL is disposed perpendicularly to the substrate 10. The nonvolatile semiconductor memory device 1C is called a VL (vertical gate ladder)-BiCS flash memory. The nonvolatile semiconductor memory device 1C includes an underlayer including the substrate 10, a plurality of electrode layers WL arranged on the underlayer, the channel body layer 20 piercing each of the plurality of electrode layers WL, and the memory layer 30A provided between the channel body layer 20 and each of the plurality of electrode layers WL.

A plurality of channel body layers 20 are provided on the substrate 10. A plurality of channel body layers 20 are stacked in the Z-direction, and extend in a direction parallel to the surface of the substrate 10 (for example, the Y-direction). Although in FIG. 6 the number of channel body layers 20 stacked in the Z-direction is three, the number is not limited thereto.

Each of the plurality of memory cells MC includes the channel body layer 20, the memory layer 30A in contact with the side surface of the channel body layer 20, and the electrode layer WL disposed on the outside of the memory layer 30A and in contact with the memory layer 30A, for example. The electrode layer WL extends in the Z-direction. When the electrode layer WL is viewed from the Z-direction, the electrode layer WL stretches across a plurality of channel body layers 20 and extends also in the X-direction. The memory layer 30A has the ONO structure described above.

A plurality of memory cells MC are connected in series in the Y-direction via the channel body layer 20 to form the memory string MS. The number of memory cells MC aligned in the Y-direction is six, but the number is not limited thereto.

In the third embodiment, a stacked body including the channel body layers 20 aligned in the Z-direction, the memory layer 30A in contact with the side surface of the channel body layer 20, and the electrode layer WL disposed on the outside of the memory layer 30A and in contact with the memory layer 30A is referred to as a fin-type stacked structure body FN. Fin-type stacked structure bodies FN are aligned in the X-direction. Although in FIG. 6 four fin-type stacked structure bodies FN are aligned in the X-direction, the number is not limited thereto.

In the nonvolatile semiconductor memory device 1C, an assist gate transistor AGT for selecting a specific fin-type stacked structure body FN is disposed between the plurality of electrode layers WL and a plurality of bit lines 48 and between the plurality of electrode layers WL and a plurality of source lines 47. The assist gate transistor AGT includes a memory layer 38m made of the same material as the memory layer 30A and an assist gate electrode 38g. The assist gate electrodes 38g aligned in the X-direction are electrically independent of one another. The assist gate electrode 38g is connected to an assist gate line (not shown) via a contact 38c.

The plurality of bit lines 48 and the plurality of source lines 47 are provided at both ends of the plurality of channel body layers 20. The bit lines 48 extend in the X-direction, and are stacked in the Z-direction. The source lines 47 extend in the X-direction, and are stacked in the Z-direction. The channel body layer 20, and the bit line 48 and the source line at the same height can be electrically connected, for example. A contact 48c is connected to each of the plurality of bit lines 48. A contact 47c is connected to each of the plurality of source lines 47. A select means (not shown) for selecting one of the plurality of channel body layers 20 is added to each of the plurality of bit lines 48 and the plurality of source lines 47.

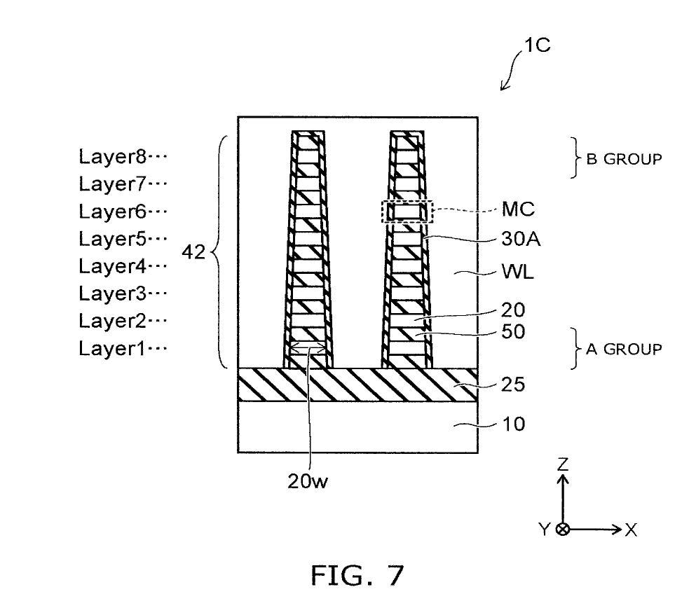

FIG. 7 is a schematic cross-sectional view of a memory cell portion according to the third embodiment.

FIG. 7 shows a cross section taken along the X-Z plane of the electrode layer WL, the memory layer 30A, and the channel body layer 20 shown in FIG. 6.

The channel body layer 20 and an insulating layer 50 are alternately stacked in the Z-direction on the substrate 10 via the insulating layer 25. A structure in which the channel body layer 20 and the insulating layer 50 are alternately stacked is referred to as a stacked body 42. The insulating layer 50 contains silicon oxide, for example. FIG. 7 shows a structure in which eight channel body layers 20 (layers 1 to 8) are stacked on an underlayer, for example.

Such a structure is formed by first preparing a stacked structure in which a plate-like channel body layer 20 and a plate-like insulating layer 50 are alternately stacked, and then forming this stacked structure using photolithography technology and etching processing. The etching processing is RIE, for example, The processed surface of the workpiece processed by RIE may have a tapered shape.

Therefore, the width 20w of the channel body layer 20 is different between the A group of lower layers and the B group of upper layers. Here, the width 20w is defined by the width in a direction (for example, the X-direction) orthogonal to the direction in which the channel body layer 20 extends (for example, the Y-direction).

The width 20w of the channel body layer 20 of the memory cell MC belonging to the A group is wider than the width 20w of the channel body layer 20 of the memory cell MC belonging to the B group, for example. The thickness of the memory layer 30A is equal between the A group and the B group.

The controller 2 can control the nonvolatile semiconductor memory device 1C such that the write speed when data are written on either of the memory cell MC belonging to the A group and the memory cell MC belonging to the B group and the write speed when data are written on the other of the memory cell MC belonging to the A group and the memory cell MC belonging to the B group are different.

Furthermore, the controller 2 can control the nonvolatile semiconductor memory device 1C such that the erase speed when data are erased from either of the memory cell MC belonging to the A group and the memory cell MC belonging to the B group and the erase speed when data are erased from the other of the memory cell MC belonging to the A group and the memory cell MC belonging to the B group are different.

The operating speed is higher in the memory cell MC belonging to the A group than in the memory cell MC belonging to the B group, for example. This is because the width 20w is wider in the A group than in the B group. Hence, data for which a high write speed/erase speed is needed are preferentially written on and erased from the memory cell MC belonging to the A group, which is lower layers. Thereby, the write speed/erase speed of the memory system is increased.

Since the width 20w is wider in the A group than in the B group, the amount of current flowing through the channel body layer 20 of the memory cell MC belonging to the A group is larger than that of the channel body layer 20 of the memory cell MC belonging to the B group. The carrier mobility of the channel body layer 20 of the memory cell MC belonging to the A group is larger than that of the channel body layer 20 of the memory cell MC belonging to the B group. Thus, data for which long time retention is required are written by the controller 2 more preferentially on the memory cell MC belonging to the A group than on the memory cell MC belonging to the B group.

The controller 2 can control the nonvolatile semiconductor memory device 1C such that the electric potential (threshold potential) of the electrode layer WL when data are written on either of the memory cell MC belonging to the A group and the memory cell MC belonging to the B group and the electric potential (threshold potential) of the electrode layer WL when data are written on the other of the memory cell MC belonging to the A group and the memory cell MC belonging to the B group are different.

Furthermore, the controller 2 can control the nonvolatile semiconductor memory device 1C such that the electric potential (threshold potential) of the electrode layer WL when data are erased from either of the memory cell MC belonging to the A group and the memory cell MC belonging to the B group and the electric potential of the electrode layer WL when data are erased from the other of the memory cell MC belonging to the A group and the memory cell MC belonging to the B group are different.

Furthermore, the controller 2 can control the nonvolatile semiconductor memory device 1C such that the number of times of reading of data stored in either of the memory cell MC belonging to the A group and the memory cell MC belonging to the B group and the number of times of reading of data stored in the other of the memory cell MC belonging to the A group and the memory cell MC belonging to the B group are different.

The width 20w of the memory cell MC belonging to the B group is narrower than the width 20w of the memory cell MC belonging to the A group, for example. In the third embodiment, the electrode layer WL is in contact with both side surfaces of the channel body layer 20 to function as double gates.

Therefore, the control power on the channel body layer 20 by the electrode layer WL is stronger in the B group than in the A group. Thereby, the memory cell MC can be operated at a lower programming voltage and a lower erase voltage in the B group than in the A group. Accordingly, the memory cell MC belonging to the B group has higher endurance, and data of a large number of times of writing repeated are written by the controller 2 preferentially on the memory cell MC belonging to the B group.

The controller 2 can control the nonvolatile semiconductor memory device 1C such that the update frequency of data stored in either of the memory cell MC belonging to the A group and the memory cell MC belonging to the B group and the update frequency of data stored in the other of the memory cell MC belonging to the A group and the memory cell MC belonging to the B group are different.

The controller 2 can write data of which the update frequency is estimated as high (for example, control data etc.) more preferentially on the memory cell MC belonging to the A group than on the B group, for example. Since the controller 2 selects a memory cell MC with higher reliability and distributes data to this memory cell MC, the reliability of the nonvolatile semiconductor memory device 1C is improved.

The controller 2 can write basic host data and important data more preferentially on the memory cell MC belonging to the A group than on the B group, for example. By host data and important data being written more preferentially on the memory cell MC belonging to the A group than on the B group, a highly reliable memory system is constructed.

The controller 2 can control the nonvolatile semiconductor memory device 1C such that the difference between the maximum value and the minimum value of the threshold voltage of the electrode layer WL when data are written on either of the memory cell MC belonging to the A group and the memory cell MC belonging to the B group and the difference between the maximum value and the minimum value of the threshold voltage of the electrode layer WL when data are written on the other of the memory cell MC belonging to the A group and the memory cell MC belonging to the B group are different.

Furthermore, the controller 2 can control the nonvolatile semiconductor memory device 1C such that the difference between the maximum value and the minimum value of the threshold voltage of the electrode layer WL when data are erased from either of the memory cell MC belonging to the A group and the memory cell MC belonging to the B group and the difference between the maximum value and the minimum value of the threshold voltage of the electrode layer WL when data are erased from the other of the memory cell MC belonging to the A group and the memory cell MC belonging to the B group are different.

The controller 2 can set the budget of the threshold voltage (Vth) in writing or erasing to different values between the A group and the B group, for example. This is because the flexibility of setting the threshold voltage is different between the A group and the B group.

Even when the same threshold voltage is applied to the A group and the B group, the control of the electrode layer (gate electrode) WL is stronger in the B group than in the A group because the width 20w is narrower in the B group, for example. That is, the electric field is applied more easily to the insulating film 33 in the B group than to the A group. Thus, the window width of the threshold voltage is wider in the B group. In the B group, the budget of the threshold voltage is set in a range of −3 V to 8 V, for example.

On the other hand, the electric field is applied less easily to the insulating film 33 in the A group than to the B group because the width 20w is wider in the A group. Thus, the window width of the threshold voltage is narrower in the A group. Here, erase operation at a strong erase voltage may cause cycle stress; hence, in the A group the budget of the threshold voltage may be set in a range of −2 V to 9 V. Thereby, the stress applied to the insulating film 33 is relaxed. Thus, the threshold voltage in each memory cell MC can be set in a range with high reliability.

The controller 2 can, when data cannot be read normally from a memory cell MC, alter the threshold voltage of this memory cell MC to perform shift read operation (described above) so that data stored in this memory cell MC can be read properly.

For example, when the controller 2 has searched an optimum shift value in the A group or the B group, the controller 2 calculates the shift value using a simple formula for the other memory cells MC, and sets a different shift value for each memory cell MC. By optimizing the shift value in shift reading, false reading of data is reduced.

The controller 2 may multiplex data, not make data into two values, and store the data in each memory cell MC of the A group and the B group. By the multiple-valued storage, a memory system good in a reliability mode is constructed. It is also possible to construct a memory system in which a logical block is configured such that a memory cell MC in an upper layer and a memory cell MC in a lower layer coexist and encoding is made. Thus, using a product code, the efficiency of remedying error data is increased.

### Fourth Embodiment

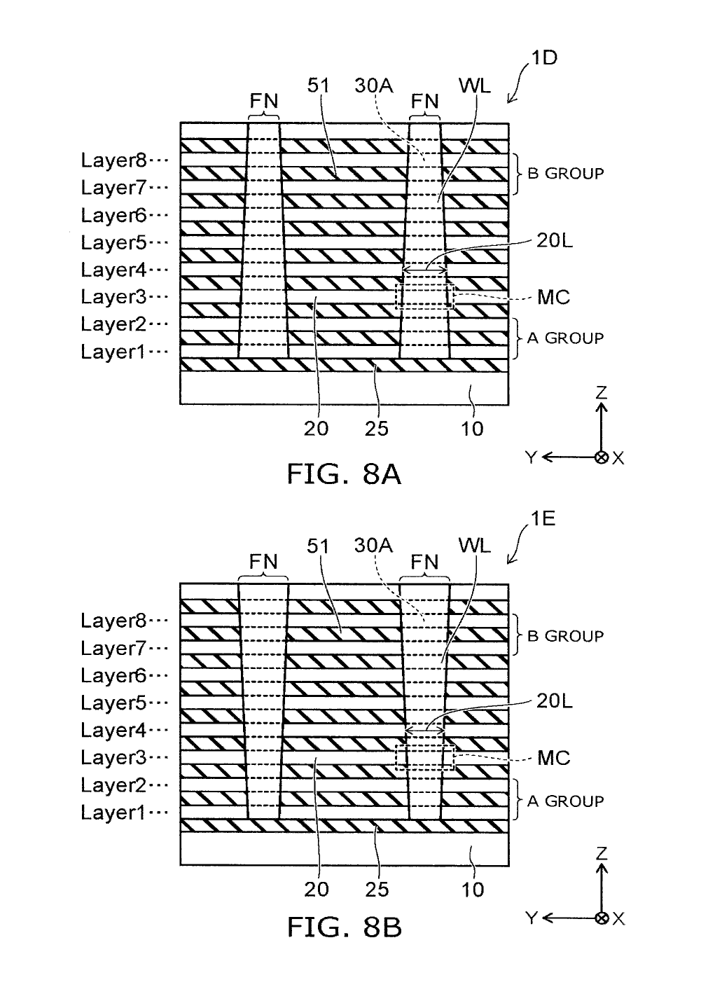

FIG. 8A and FIG. 8B are schematic side views of memory cell portions according to a fourth embodiment.

FIG. 8A and FIG. 8B show a side surface of the electrode layer WL, the memory layer 30A, and the channel body layer 20 shown in FIG. 6 as viewed from the direction perpendicular to the Y-Z plane. FIG. 8A and FIG. 8B show a state where an interlayer insulating film 51 is provided between the over- and underlying electrode layers WL. In FIG. 6, the illustration of the interlayer insulating film 51 is omitted.

In FIG. 8A, the width of the electrode layer WL in the Y-direction is wider in a lower layer; and in FIG. 8B, the width of the electrode layer WL in the Y-direction is wider in an upper layer. Here, the thickness of the memory layer 30A is equal between the A group and the B group.

In nonvolatile semiconductor memory devices 1D and 1E, in the direction in which the channel body layer 20 extends (for example, the Y-direction), the length 20L of the channel body layer 20 in contact with the memory layer 30A (channel length) is different between the A group and the B group. This is because the fin-type stacked structure body FN is formed by dry etching technique, and at this time, the length 20L may become shorter in an upper layer (FIG. 8A) or longer in an upper layer (FIG. 8B), depending on the etching conditions and the mask material.

A shorter length 20L leads to a smaller area of the charge storage film 32 in contact with the channel body layer 20. In this case, the shift amount of the threshold voltage in writing/erasing is smaller.

An impurity element (arsenic (As), phosphorus (P), or the like) is implanted into the channel body layer 20 in order to form a source/drain diffusion region in the channel body layer 20, for example. At this time, in a memory cell MC with a shorter length 20L, the impurity element goes round to the channel more easily, and the proportion of the source/drain diffusion region to the length 20L is larger. As a result, in the memory cell MC with a shorter length 20L, the short channel effect will occur to lead to a smaller shift amount of the threshold voltage in reading.

In other words, a memory cell MC with a longer length 20L has a wider window width in writing/erasing. In such a case, when writing/erasing is repeated with a window width of the same threshold voltage on a memory cell MC with a longer length 20L and a memory cell MC with a shorter length 20L, the memory cell MC with a longer length 20L exhibits higher endurance than the memory cell MC with a shorter length 20L.

Thus, it is preferable that data for which a wide window width in writing/erasing is required and data for which repeated writing is required be written preferentially on a memory cell MC with a longer length 20L. For example, data are stored in the memory cell MC belonging to the A group in the nonvolatile semiconductor memory device 1D, and are stored in the memory cell MC belonging to the B group in the nonvolatile semiconductor memory device 1E. Thereby, a highly reliable memory system is provided.

### Fifth Embodiment

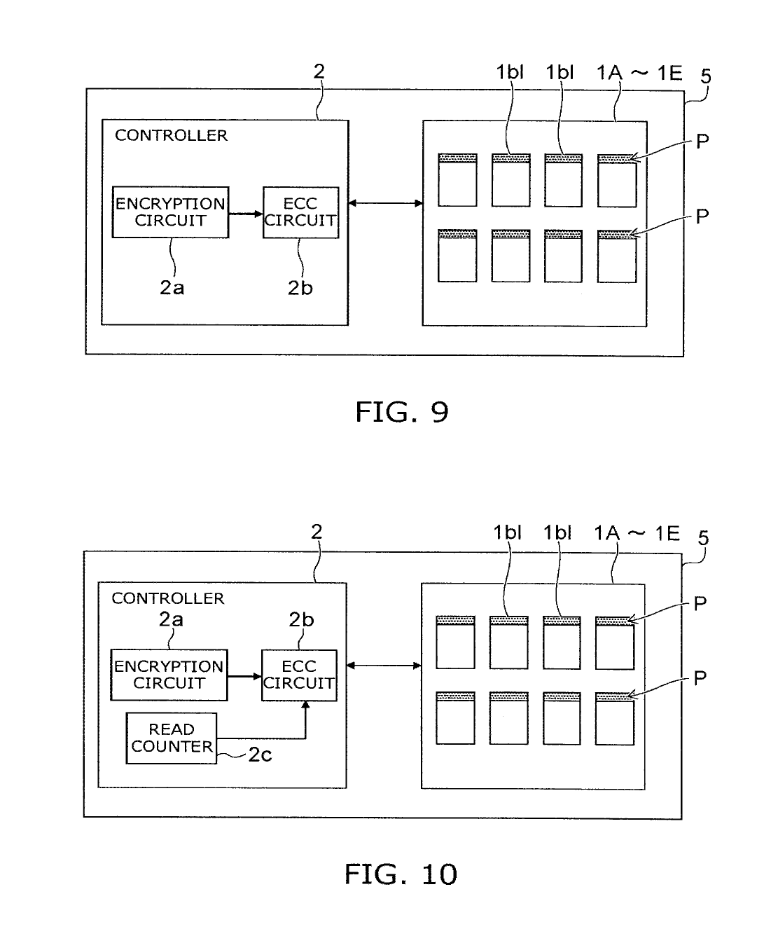

FIG. 9 is a block diagram of a memory system according to a fifth embodiment.

In the memory system 5, a plurality of memory cells MC are separated into a plurality of blocks 1bl. In the fifth embodiment, in the case where the read voltage of the memory cell MC belonging to one of the plurality of blocks 1bl is shifted to a target value or more, the controller 2 makes the control of transferring data stored in this block 1bl to another block.

In each block 1bl of the nonvolatile semiconductor memory devices 1A to 1E, part of the memory cells MC that are susceptible to read disturb (RD) are used as a monitor for the read disturb (RD) level, for example. In FIG. 9, the memory cell MC susceptible to read disturb (RD) is shown by arrow P as an example. Here, it is assumed that in the block 1bl, the memory cell MC in an upper layer shown by arrow P is more susceptible to read disturb (RD). In this case, the memory cell MC shown by arrow P is used as a monitor for the level read disturb (RD) level. In the case where a memory cell MC in a lower layer is more susceptible to read disturb (RD), the memory cell MC in a lower layer may be used as a monitor for the level read disturb (RD) level.

The memory cell MC monitoring read disturb (RD) may deteriorate due to repeated read operation, and the threshold voltage thereof may be shifted. When the shift amount (ΔVth) has exceeded a reference value, the controller 2 makes the control of transferring data stored in this block 1bl to another block 1bl.

By providing the memory cell MC for monitoring read disturb (RD) in the block 1bl, it becomes unnecessary to continue to use a memory cell MC that has experienced the influence of read disturb (RD). The controller 2 transfers data to another block 1bl before reliability is reduced due to the influence of read disturb (RD). Thereby, the reliability of the memory system is improved.

The memory cell MC for monitoring read disturb (RD) is provided in the block 1bl, not outside the block 1bl. Therefore, a surplus chip area is suppressed, and the chip size is not increased.

### Sixth Embodiment

FIG. 10 is a block diagram of a memory system according to a sixth embodiment.

In the sixth embodiment, the controller 2 can count the number of times of reading in each of the plurality of blocks 1bl. When the number of times of reading has become a target value or more, the controller 2 transfers data stored in the block 1bl in which the number of times of reading has become the target value or more to another block 1bl. The controller 2 includes a read counter 2c that counts the number of times of reading.

In a memory cell MC in which reading has been performed repeatedly 1000 times (for example, the memory cell MC shown by arrow P), the threshold voltage is degraded, for example. In the case where the shift amount (ΔVth) thereof has exceeded a reference value, the controller 2 makes the control of transferring data stored in that block 1bl to another block 1bl.

By providing the read counter 2c, it becomes unnecessary to continue to use a memory cell MC that has experienced the influence of read disturb (RD). The controller 2 transfers data to another block 1bl before reliability is reduced due to the influence of read disturb (RD). Thereby, the reliability of the memory system is improved.

### Seventh Embodiment

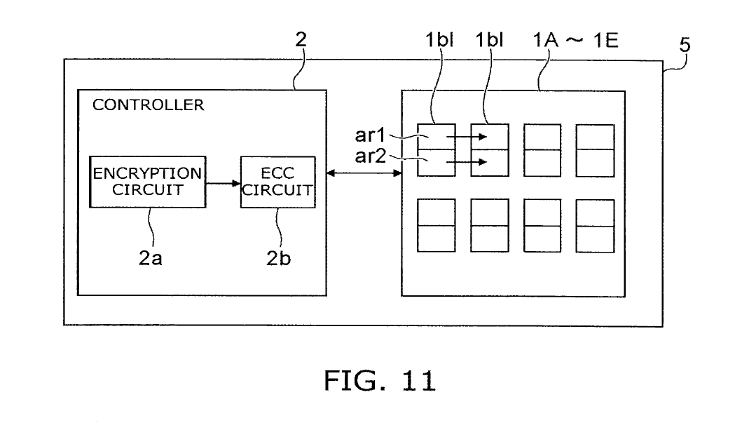

FIG. 11 is a block diagram of a memory system according to a seventh embodiment.

In the seventh embodiment, each of the plurality of blocks 1bl is separated into area ar1 and area ar2. The controller 2 can transfer data stored in either of area ar1 and area ar2 in a block 1bl to either of area ar1 and area ar2 in another block 1bl. The arrow stretching from a block 1bl to another block 1bl in the drawing expresses a manner in which data are transferred between the blocks 1bl.

When operation is performed separately in area ar1 of upper layers and area ar2 of lower layers of the block 1bl (this operation is referred to as block division erase operation), a difference occurs in update frequency between area ar1 and area ar2 in the block 1bl. In the seventh embodiment, a memory cell MC with a smaller update frequency is regarded as a memory cell MC with a longer lifetime, and writing is performed repeatedly on this memory cell MC.

A case is assumed where block division erase operation is performed in a nonvolatile semiconductor memory device in which a memory cell MC in a lower layer has higher endurance for rewriting than a memory cell MC in an upper layer, for example. In this case, it is assumed that area ar1 of upper layers is cycle-degraded earlier than area ar2 of lower layers.

In this case, the controller 2 transfers data stored in area ar1 of upper layers to another block 1bl, without using the memory cell MC belonging to area ar1 of upper layers. On the other hand, area ar2 of lower layers is continued to be used because the memory cell MC belonging to area ar2 of lower layers is still rewritable.

At this time, the controller 2 can finish using the memory cell MC in area ar1 of upper layers on which rewriting has been performed a prescribed number of times (for example, 1300 times), and transfer data to another block 1bl. For the memory cell MC belonging to area ar2 of lower layers, the controller 2 performs rewriting on the memory cell MC up to a certain number of times (for example, 3600 times) exceeding the number of times mentioned above, and then makes the control of transferring data to another block 1bl.

Thus, after that, a memory cell MC that is still rewritable can be continued to be used, without using a memory cell MC with a high update frequency in which the reliability of operation has been reduced. In other words, in the seventh embodiment, the memory cell is utilized effectively up to the number of times it can be used. Consequently, the reliability of the memory system is improved.

In the embodiment, a BiCS flash memory or a VL-BiCS flash memory has been described. The embodiment can be applied also to other nonvolatile semiconductor memory devices of a three-dimensionally stacked structure (for example, VG-NAND, VG-FG, etc.).

Although the embodiments are described above with reference to the specific examples, the embodiments are not limited to these specific examples. That is, design modification appropriately made by a person skilled in the art in regard to the embodiments is within the scope of the embodiments to the extent that the features of the embodiments are included. Components and the disposition, the material, the condition, the shape, and the size or the like included in the specific examples are not limited to illustrations and can be changed appropriately.

The components included in the embodiments described above can be combined to the extent of technical feasibility and the combinations are included in the scope of the embodiments to the extent that the feature of the embodiments is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A memory system comprising:
a nonvolatile semiconductor memory device including a plurality of memory cells; and
a controller configured to control one of read operation, write operation, and a use frequency of the read operation or the write operation on the nonvolatile semiconductor memory device, and configured to change controlling for a memory cell belonging to a first group of the memory cells and to change controlling for a memory cell belonging to a second group located on an upper side or a lower side of the memory cell belonging to the first group.

2. The system according to claim 1, wherein
the nonvolatile semiconductor memory device includes
an underlayer,
a stacked body provided on the underlayer, each of a plurality of electrode layers and each of a plurality of insulating layers being alternately stacked in the stacked body,
a channel body layer extending from an upper end of the stacked body to a lower end of the stacked body, and
a memory layer provided between the channel body layer and each of the electrode layers, surrounded by each of the electrode layers, and surrounding the channel body layer,
each of the memory cells includes the memory layer, the channel body layer in contact with the memory layer, and the electrode layer in contact with the memory layer, and
a thickness of the memory layer when the memory cells are cut so as to be orthogonal to a stacking direction of the stacked body is equal between the first group and the second group, and a cross-sectional area of the memory layer is different between the first group and the second group.

3. The system according to claim 1, wherein
the nonvolatile semiconductor memory device includes an underlayer,
a stacked body provided on the underlayer, each of a plurality of electrode layers and each of a plurality of insulating layers being alternately stacked in the stacked body,
a channel body layer extending from an upper end of the stacked body to a lower end of the stacked body, and
a memory layer provided between the channel body layer and each of the electrode layers, surrounded by each of the electrode layers, and surrounding the channel body layer,
each of the memory cells includes the memory layer, the channel body layer in contact with the memory layer, and the electrode layer in contact with the memory layer,
a thickness of the channel body layer is different between the first group and the second group, and
a thickness of the memory layer is different between the first group and the second group.

4. The system according to claim 1, wherein
the nonvolatile semiconductor memory device includes
an underlayer,
a plurality of electrode layers arranged on the underlayer,
a channel body layer piercing each of the electrode layers, and
a memory layer provided between the channel body layer and each of the electrode layers,
each of the memory cells includes the memory layer, the channel body layer in contact with the memory layer, and the electrode layer in contact with the memory layer,
a width of the channel body layer in a direction orthogonal to a direction in which the channel body layer extends is different between the first group and the second group, and
a thickness of the memory layer is equal between the first group and the second group.

5. The system according to claim 1, wherein
the nonvolatile semiconductor memory device includes
an underlayer,
a plurality of electrode layers arranged on the underlayer,
a channel body layer piercing each of the electrode layers, and
a memory layer provided between the channel body layer and each of the electrode layers,
each of the memory cells includes the memory layer, the channel body layer in contact with the memory layer, and the electrode layer in contact with the memory layer,
a length of the channel body layer in contact with the memory layer is different between the first group and the second group in a direction in which the channel body layer extends, and
a thickness of the memory layer is equal between the first group and the second group.

6. The system according to claim 1, wherein an update frequency of data stored in one of the memory cell belonging to the first group and the memory cell belonging to the second group and an update frequency of data stored in one other of the memory cell belonging to the first group and the memory cell belonging to the second group are different.

7. The system according to claim 1, wherein a storage time of data stored in one of the memory cell belonging to the first group and the memory cell belonging to the second group and a storage time of data stored in one other of the memory cell belonging to the first group and the memory cell belonging to the second group are different.

8. The system according to claim 1, wherein a number of times of writing of data to be stored in one of the memory cell belonging to the first group and the memory cell belonging to the second group and a number of times of writing of data to be stored in one other of the memory cell belonging to the first group and the memory cell belonging to the second group are different.

9. The system according to claim 1, wherein a write speed when data are written on one of the memory cell belonging to the first group and the memory cell belonging to the second group and a write speed when data are written on one other of the memory cell belonging to the first group and the memory cell belonging to the second group are different.

10. The system according to claim 1, wherein an erase speed when data are erased from one of the memory cell belonging to the first group and the memory cell belonging to the second group and an erase speed when data are erased from one other of the memory cell belonging to the first group and the memory cell belonging to the second group are different.

11. The system according to claim 1, wherein a number of times of reading of data stored in one of the memory cell belonging to the first group and the memory cell belonging to the second group and a number of times of reading of data stored in one other of the memory cell belonging to the first group and the memory cell belonging to the second group are different.

12. The system according to claim 1, wherein an electric potential of the electrode layer when data are written on one of the memory cell belonging to the first group and the memory cell belonging to the second group and an electric potential of the electrode layer when data are written on one other of the memory cell belonging to the first group and the memory cell belonging to the second group are different.

13. The system according to claim 1, wherein an electric potential of the electrode layer when data are erased from one of the memory cell belonging to the first group and the memory cell belonging to the second group and an electric potential of the electrode layer when data are erased from one other of the memory cell belonging to the first group and the memory cell belonging to the second group are different.

14. The system according to claim 1, wherein a difference between a maximum value and a minimum value of a voltage of the electrode layer when data are written on one of the memory cell belonging to the first group and the memory cell belonging to the second group and a difference between a maximum value and a minimum value of a voltage of the electrode layer when data are written on one other of the memory cell belonging to the first group and the memory cell belonging to the second group are different.

15. The system according to claim 1, wherein a difference between a maximum value and a minimum value of a voltage of the electrode layer when data are erased from one of the memory cell belonging to the first group and the memory cell belonging to the second group and a difference between a maximum value and a minimum value of a voltage of the electrode layer when data are erased from one other of the memory cell belonging to the first group and the memory cell belonging to the second group are different.

16. The system according to claim 1, wherein
the memory cells are separated into a plurality of blocks and
the controller is capable of transferring data stored in one of the blocks to one other of the blocks when a read voltage of a memory cell belonging to the one of the blocks is shifted to a target value or more.

17. The system according to claim 1, wherein
the memory cells are separated into a plurality of blocks and
the controller is capable of counting a number of times of reading in each of the blocks and is capable of transferring data stored in the each of the blocks in which the number of times of reading has become a target value or more to one other of the blocks when the number of times of reading has become the target value or more.

18. The system according to claim 1, wherein
the memory cells are separated into a plurality of blocks,
each of the blocks is separated into a first area and a second area, and
the controller is capable of transferring data stored in one of the first area and the second area in one of the blocks to one of the first area and the second area in one other of the blocks.

19. The system according to claim 1, wherein the controller is capable of shifting an electric potential of the electrode layer when data are written on one of the memory cells or an electric potential of the electrode layer when data are erased from one of the memory cells.

20. The system according to claim 1, wherein the controller multiplexes data and stores the data in one of the memory cells.
